(19) United States
(12) Patent Application Publication
(10) Pub. No.: US 2006/0145785 A1
(43) Pub. Date: Jul. 6, 2006

(54) Piezoelectric resonator and method for manufacturing the same

(76) Inventors: Motonori Ishii, Osaka (JP); Kazuhiro Yahata, Osaka (JP); Naohiro Tsurumi, Kyoto (JP)

Correspondence Address: MCDERMOTT WILL & EMERY LLP, 600 13TH STREET, N.W., WASHINGTON, DC, 20005-3096, US

(21) Appl. No.: 11/322,248

(22) Filed: Jan. 3, 2006

(30) Foreign Application Priority Data
Jan. 5, 2005 (JP) 2005-000853

(51) Int. Cl. H03H 9/54

(52) U.S. Cl. 333/187

(57) ABSTRACT

A piezoelectric resonator includes a substrate, an acoustic mirror formed on the substrate and includes alternately stacked first acoustic mirror material layers and second acoustic mirror material layers having higher acoustic impedance than that of the first acoustic mirror material layers, a piezoelectric film formed on the acoustic mirror, a top electrode formed on the piezoelectric film and a bottom electrode formed below the piezoelectric film. A bonding interface is provided between metal films bonded to each other between the substrate and the piezoelectric film.

### CROSS-REFERENCE TO RELATED APPLICATION

This non-provisional application claims priority under 35 U.S.C. §119(a) of Japanese Patent Application No. 2005-853 filed in Japan on Jan. 5, 2005, the entire contents of which are hereby incorporated by reference.

### BACKGROUND OF THE INVENTION

1. Field of the Invention

The present invention relates to a resonator which is applicable to a high frequency filter in an electronic circuit, particularly to an acoustic resonator which makes use of the resonance of a piezoelectric substance.

2. Description of Related Art

According to global dissemination of cellular phones in recent years, a small-sized, high performance filter has been demanded. A resonator is one of the components of the filter. Aiming at size reduction and improvement in performance of the filter, attempts have been made to the manufacture of a filter including a SAW resonator using surface acoustic waves or a piezoelectric resonator using bulk acoustic waves. Hereinafter, the operation principles of the piezoelectric resonator using the bulk acoustic waves will be explained with reference to the drawings.

FIG. 9 is a sectional view illustrating the structure of a conventional piezoelectric resonator using bulk acoustic waves (see Japanese Unexamined Patent Publication No. H6-295181, for example). The conventional piezoelectric bulk acoustic wave resonator has a resonance frequency of about 2 GHz and is in the form of a polygon 100 to 200 μm on a side or circular when viewed in plan. As shown in the sectional view of FIG. 9, a piezoelectric film 201 of about 500 nm thick made of aluminum nitride (AlN) is formed on a substrate 204 provided with an opening 205. A 300 nm thick top electrode 202 and a 300 nm thick bottom electrode 203, both of which are made of molybdenum (Mo), are formed on the top and bottom surfaces of the piezoelectric film 201, respectively.

When high frequency power is applied to the top and bottom electrodes 202 and 203, a high frequency electric field is induced in the piezoelectric film 201. Due to the piezoelectric characteristic of the piezoelectric film 201, ultrasonic waves having the same frequency as that of the electric field are generated in the piezoelectric film 201. In general, the induced ultrasonic waves are attenuated in the piezoelectric film 201, top electrode 202, bottom electrode 203 and substrate 204. However, if the piezoelectric film 201 is significantly thicker than the top and bottom electrodes 202 and 203, the ultrasonic waves having a frequency f represented by the equation (1) become standing waves in the thickness direction of the piezoelectric film 201 and are not attenuated.
f=nV/2d (1)
(wherein n is an integer of 1 or more, V is acoustic velocity in the thickness direction of the piezoelectric film 201, d is the sum of the thicknesses of the piezoelectric film 201, top electrode 202 and bottom electrode 203.)

Due to the piezoelectric characteristic of the piezoelectric film 201, the ultrasonic waves at the frequency f induce an electric field having the frequency f. Therefore, unlike the other frequencies, high frequency waves at the frequency f are solely allowed to pass between the top and bottom electrodes 202 and 203. The frequency f is called resonance frequency. The impedance between the top and bottom electrodes 202 and 203 shows the minimum peak at the resonance frequency f.

In the piezoelectric bulk acoustic wave resonator, a region that induces ultrasonic waves in the thickness direction (hereinafter this is referred to a cavity region) oscillates in the vertical direction. Therefore, it is necessary to prevent the attenuation of the vertical oscillation by the substrate or a sealant. For this reason, the cavity section must be free from contact from above and below.

In the common piezoelectric resonator as shown in FIG. 9, the top electrode 202 of the cavity section is free from contact from above and the opening 205 is provided below the bottom electrode 203 of the cavity section. Therefore, the attenuation of the vertical oscillation by the substrate 204 is prevented.

In general, however, it is not easy to form the opening 205 in the substrate 204. The opening 205 is usually formed by etching the bottom of the substrate 204, but it takes a long time because the substrate 204 is usually 100 μm or more in thickness. Moreover, the diameter of the opening 205 becomes larger at the bottom than at the top, although it is ideal to keep the diameter uniform. As a solution to this problem, the top surface of the substrate 204 is partially cut away to form a recess in the cavity section such that hollow space is formed below the bottom surface of the bottom electrode 203.

What is in common among these structures is that the cavity section is suspended in the air while only the periphery of the cavity section is supported. Therefore, the cavity section is significantly mechanically fragile. When downward force is applied from above to the cavity section, the cavity section easily falls in. Therefore, care must be taken to prevent the break of the cavity section in the manufacturing steps. However, this makes the manufacturing steps complicated.

As a solution to the mechanical fragility of the cavity section, a piezoelectric resonator using an acoustic mirror is disclosed (see Japanese Unexamined Patent Publication No. H6-295181). Specifically, a piezoelectric film provided with a top electrode and a bottom electrode is formed on an acoustic mirror including alternately stacked first acoustic mirror material layers and second acoustic mirror material layers.

The first acoustic mirror material layers and the second acoustic mirror material layers are made of materials which are greatly different in acoustic impedance. By so doing, reflection of acoustic waves occurs at the interfaces between the first and second acoustic material layers. At this time, the frequency of the acoustic waves reflected by the acoustic mirror is determined by the characteristic of the acoustic mirror determined by the thickness of the first and second acoustic mirror material layers. If the determined frequency is set to the same as the resonance frequency of the piezoelectric resonator, the same effect is obtained as that obtained when the hollow space or opening is provided below the cavity section of the piezoelectric resonator. Specifically, acoustic energy generated in the piezoelectric resonator is confined in the cavity section without diffusing the energy downward.

### SUMMARY OF THE INVENTION

As to the piezoelectric resonator using the conventional acoustic mirror, the piezoelectric film must be deposited on the acoustic mirror. As the acoustic mirror is formed by alternately stacking the first acoustic mirror material layers and the second acoustic mirror material layers at least about 6 times, it is very difficult to keep the uppermost surface of the acoustic mirror flat. Further, the acoustic mirror is likely to warp because the first and second acoustic mirror material layers have different thermal expansion coefficients.

If the bottom electrode is formed on the acoustic mirror which is not flat enough, the thickness of the piezoelectric film formed thereon becomes uneven. Further, if the piezoelectric film is formed on the warped non-flat surface, the piezoelectric film deteriorates in crystallinity.

The characteristic of the piezoelectric resonator greatly depends on the piezoelectric film. The poor crystallinity of the piezoelectric film indicates that there are many crystal defects and grain boundaries in the piezoelectric film. Therefore, ultrasonic waves generated in the piezoelectric film are attenuated by the crystal defects and the grain boundaries, whereby the energy is lost. This brings about an increase in insertion loss of the piezoelectric resonator and leads to characteristic deterioration. When the thickness of the piezoelectric film is not uniform, the resonance frequency of the piezoelectric resonator varies, thereby deteriorating the frequency selectivity of the piezoelectric resonator.

Further, in the piezoelectric resonator using the conventional acoustic mirror, the crystallinity of the piezoelectric film is low and the thickness of the piezoelectric film becomes uneven. As a result, the insertion loss increases and the frequency selectivity deteriorates.

Also in the case of the piezoelectric resonator using the acoustic mirror, when the substrate provided with the piezoelectric resonator is packaged, the cavity section needs to be free from contact from above to prevent the attenuation of the vertical oscillation. If resin seal packaging, which is cost-effective, is adopted, the resin contacts the top of the cavity section. Therefore, the resin seal packaging is not suitable for the piezoelectric resonator. Further, as moisture deteriorates the performance of the piezoelectric resonator, it is necessary to block the entrance of the moisture by hermetically packaging the piezoelectric resonator. Therefore, though it is expensive, the piezoelectric resonator must be hermetically packaged with the cavity portion kept free from contact from above.

In order to solve the above-described problems, the present invention makes it possible to use a piezoelectric film with high crystallinity and excellent flatness in a piezoelectric resonator including an acoustic mirror, thereby achieving a piezoelectric resonator with less insertion loss and high frequency selectivity and a method for manufacturing the same.

Specifically, a piezoelectric resonator according to the present invention includes: a substrate; an acoustic mirror formed on the substrate and includes alternately stacked first acoustic mirror material layers and second acoustic mirror material layers having higher acoustic impedance than that of the first acoustic mirror material layers; a piezoelectric film formed on the acoustic mirror; a top electrode formed on the piezoelectric film; and a bottom electrode formed below the piezoelectric film, wherein a bonding interface is provided between metal films bonded to each other between the substrate and the piezoelectric film.

In the piezoelectric resonator of the present invention, the acoustic mirror is arranged below the highly crystalline and flat piezoelectric film which has been formed on the preparation substrate. Therefore, there is no need of taking care of the flatness of the acoustic mirror. As a result, the piezoelectric resonator is achieved easily with less insertion loss and excellent frequency selectivity.

In the piezoelectric resonator of the present invention, it is preferred that the first acoustic mirror material layers are made of any one of silicon oxide, aluminum, titanium and gallium nitride. It is also preferred that the second acoustic mirror material layers are made of any one of tungsten, iridium, aluminum nitride and molybdenum. By so doing, the acoustic mirror is obtained with reliability.

It is preferred that the piezoelectric resonator of the present invention further includes adhesion layers which are formed between the substrate and the acoustic mirror and made of metal, wherein the bonding interface is provided between the adhesion layers. The bonding interface may preferably be provided in the bottom electrode. This makes it possible to use a piezoelectric film with excellent crystallinity and flatness in the piezoelectric resonator including the acoustic mirror.

In the piezoelectric resonator of the present invention, it is preferred that the metal films for providing the bonding interface are made of gold, a gold-tin alloy, a gold-germanium alloy or a lead-tin alloy. By so doing, the bonding interface is provided with reliability.

It is preferred that the piezoelectric resonator of the present invention further includes a first barrier metal layer which is formed between the bottom electrode and the acoustic mirror to prevent interdiffusion between the bottom electrode and the acoustic mirror. The first barrier metal layer is preferably made of nickel or platinum. As the above-described features prevent the interdiffusion from occurring between the bottom electrode and the acoustic mirror, changes in composition and structure of the bottom electrode and the acoustic mirror are surely avoided.

It is preferred that the piezoelectric resonator of the present invention further includes a top acoustic mirror formed on the top electrode and includes the first acoustic mirror material layers and the second acoustic mirror material layers which are alternately stacked. Accordingly, the need of providing keeping the piezoelectric resonator free from contact from above is eliminated, thereby allowing the resin seal packaging of the piezoelectric resonator. Further, the top electrode is preferably made of metal films bonded to each other. Accordingly, the top acoustic mirror is formed by bonding.

It is preferred that the piezoelectric resonator of the present invention further includes a second barrier metal layer which is formed between the top electrode and the top acoustic mirror to prevent interdiffusion between the top electrode and the top acoustic mirror. The second barrier metal layer is preferably made of nickel or platinum.

A first method for manufacturing a piezoelectric resonator according to the present invention includes the steps of: (a) alternately stacking first acoustic mirror material layers and second acoustic mirror material layers having higher impedance than that of the first acoustic mirror material layers on a first substrate to form an acoustic mirror and forming a first bottom electrode layer on the acoustic mirror; (b) forming a piezoelectric film on a second substrate and forming a second bottom electrode layer on the piezoelectric film; (c) bonding the first bottom electrode layer formed above the first substrate and the second bottom electrode layer formed above the second substrate to form a bottom electrode; and (d) removing the second substrate from the piezoelectric film.

According to the first method for manufacturing a piezoelectric resonator, there is no need of forming the piezoelectric film on the acoustic mirror, i.e., there is no need of taking care of the flatness of the acoustic mirror. Therefore, the piezoelectric resonator is easily manufactured with less insertion loss and excellent frequency selectivity.

In the first method for manufacturing a piezoelectric resonator, it is preferred that the first bottom electrode layer and the second bottom electrode layer are both made of gold and the step (c) is the step of bonding the first bottom electrode layer and the second bottom electrode layer by thermocompression bonding. It may be preferred that the first bottom electrode layer and the second bottom electrode layer are made of a gold-tin alloy, a gold-germanium alloy or a lead-tin alloy and the step (c) is the step of bonding the first bottom electrode layer and the second bottom electrode layer by eutectic bonding. According to these steps, the first and second bottom electrode layers are surely bonded to each other.

In the first method for manufacturing a piezoelectric resonator, it is preferred that the step (a) includes the step of forming a first barrier metal layer between the acoustic mirror and the first bottom electrode layer to prevent interdiffusion between the acoustic mirror and the bottom electrode. The first barrier metal layer is preferably made of nickel or platinum. As the above-described features prevent the interdiffusion from occurring between the bottom electrode and the acoustic mirror, changes in composition and structure of the bottom electrode and the acoustic mirror are surely avoided.

It is preferred that the first method for manufacturing a piezoelectric resonator includes, after the step (d), the steps of: (e) forming a top electrode on the piezoelectric film from which the second substrate has been removed; and (f) alternately stacking the first acoustic mirror material layers and the second acoustic mirror materials on the top electrode to form a top acoustic mirror. According to these steps, the need of keeping the piezoelectric resonator free from contact from above is eliminated. This makes it possible to package the piezoelectric resonator by resin sealing.

It is preferred that the first method for manufacturing a piezoelectric resonator includes, after the step (d), the steps of: (g) forming a first top electrode layer on the piezoelectric film from which the second substrate has been removed; (h) alternately stacking the first acoustic mirror material layers and the second acoustic mirror material layers on a third substrate to form a top acoustic mirror and forming a second top electrode layer on the top acoustic mirror; (i) bonding the first top electrode layer and the second top electrode layer to form a top electrode; and (j) removing the third substrate from the top acoustic mirror. Through these steps, the top acoustic mirror is formed with reliability.

In this case, it is preferred that the first top electrode layer and the second top electrode layer are both made of gold and the step (i) is the step of bonding the first top electrode layer and the second top electrode layer by thermocompression bonding. Further, it may preferred that the first top electrode layer and the second top electrode layer are made of a combination of gold and tin, gold and germanium or lead and tin and the step (i) is the step of bonding the first top electrode layer and the second top electrode layer by eutectic bonding.

It is preferred that the step (h) includes the step of forming a second barrier metal layer between the top acoustic mirror and the second top electrode layer to prevent interdiffusion between the top acoustic mirror and the top electrode. In such a case, the second barrier metal layer is preferably made of nickel or platinum.

A second method for manufacturing a piezoelectric resonator according to the present invention includes the steps of: (a) forming a first adhesion layer on a first substrate; (b) forming a piezoelectric film, a bottom electrode, an acoustic mirror including alternately stacked first acoustic mirror material layers and second acoustic mirror material layers having higher impedance than that of the first acoustic mirror material layers and a second adhesion layer in this order on a second substrate; (c) bonding the first adhesion layer formed on the first substrate and the second adhesion layer formed above the second substrate; and (d) removing the second substrate from the piezoelectric film.

According to the second method for manufacturing a piezoelectric resonator according to the present invention, it is not necessary to form the bottom electrode with adhesive material. Therefore, the material for the bottom electrode is freely selected from a wide choice.

According to the second method for manufacturing a piezoelectric resonator according to the present invention, it is preferred that the first adhesion layer and the second adhesion layer are both made of gold and the step (c) is the step of boding the first adhesion layer and the second adhesion layer by thermocompression bonding. It may be preferred that the first adhesion layer and the second adhesion layer are made of a combination of gold and tin, gold and germanium or lead and tin and the step (c) is the step of boding the first adhesion layer and the second adhesion layer by eutectic bonding.

It is preferred that the second method for manufacturing a piezoelectric resonator according to the present invention further includes after the step (d), the steps of: (i) forming a top electrode on the piezoelectric film; and (j) alternately stacking the first acoustic mirror material layers and the second acoustic mirror material layers on the top electrode to form a top acoustic mirror.

### BRIEF DESCRIPTION OF THE DRAWINGS

FIG. 1 is a sectional view illustrating a piezoelectric resonator according to a first embodiment of the present invention.

FIGS. 2A to 2E are sectional views illustrating the steps of manufacturing the piezoelectric resonator according to the first embodiment of the present invention.

FIG. 3 is a sectional view illustrating a variant of the piezoelectric resonator according to the first embodiment of the present invention.

FIGS. 4A to 4D are sectional views illustrating the steps of manufacturing the variant of the piezoelectric resonator according to the first embodiment of the present invention.

FIG. 5 is a sectional view illustrating a piezoelectric resonator according to a second embodiment of the present invention.

FIGS. 6A to 6D are sectional views illustrating the steps of manufacturing the piezoelectric resonator according to the second embodiment of the present invention.

FIG. 7 is a sectional view illustrating a piezoelectric resonator according to a third embodiment of the present invention.

FIG. 8 is a sectional view illustrating a variant of a piezoelectric resonator according to the third embodiment of the present invention.

FIG. 9 is a sectional view illustrating a conventional piezoelectric resonator.

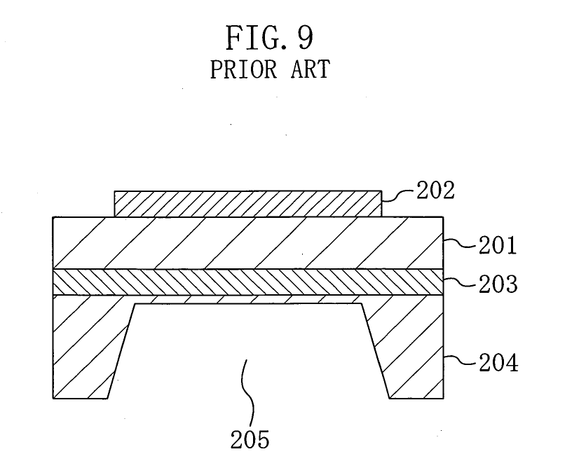

### DETAILED DESCRIPTION OF THE INVENTION

### FIRST EMBODIMENT

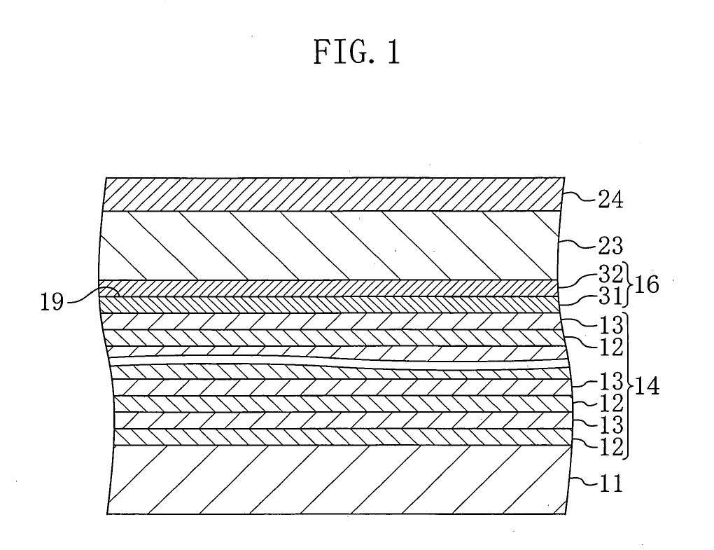

FIG. 1 is a sectional view illustrating the structure of a piezoelectric resonator according to the first embodiment of the present invention. As shown in FIG. 1, the piezoelectric resonator of the present embodiment includes an acoustic mirror.

On a substrate 11 made of silicon (Si), four first acoustic mirror material layers 12 made of silicon oxide (SiO₂) and four second acoustic mirror material layers 13 made of tungsten (W) are stacked alternately to form an acoustic mirror 14. The thickness of the first and second acoustic mirror material layers 12 and 13 is controlled such that the wavelengths of the first and second acoustic mirror material layers 12 and 13 become ¼ of the resonance frequency. For example, when the resonance frequency is 2 GHz, the thickness is 200 to 500 nm.

A bottom electrode 16 including first and second adhesion layers 31 and 32, both of which are made of gold (Au) and have a thickness of about 150 nm, is formed on the acoustic mirror 14. A bonding interface 19 is provided between the first and second adhesion layers 31 and 32.

A piezoelectric film 23 made of aluminum nitride (AlN) is formed on the bottom electrode 16 in a thickness of about 500 nm. A top electrode 24 made of molybdenum (Mo) is formed on the piezoelectric film 23 in a thickness of about 300 nm. The thicknesses of top electrode 24, piezoelectric film 23, bottom electrode 16 and acoustic mirror 14 are controlled depending on the resonance frequency of the resonator.

The acoustic mirror 14 is preferably formed by alternately stacking material layers having low acoustic impedance and material layers having high acoustic impedance 4 to 8 times. The first acoustic mirror material layer 12 may be made of any one of SiO₂, aluminum (Al), titanium (Ti) and gallium nitride (GaN). The second acoustic mirror material layers 13 may be made of any one of W, iridium (Ir), aluminum nitride (AlN) and molybdenum (Mo). The order of stacking the first and second acoustic mirror material layers 12 and 13 is not particularly limited as long as they are stacked alternately.

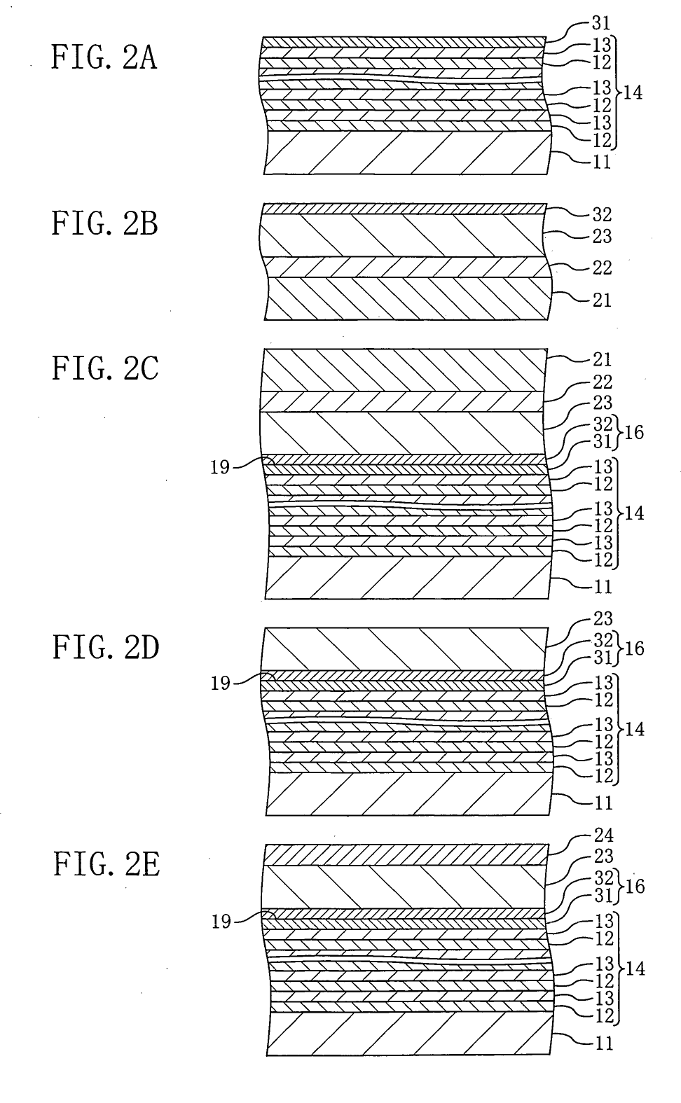

Hereinafter, an explanation of a method for manufacturing the piezoelectric resonator of the present embodiment will be provided. FIGS. 2A to 2E are sectional views illustrating the steps of manufacturing the piezoelectric resonator of the present embodiment. As shown in FIG. 2A, six 300 nm thick first acoustic mirror material layers 12 made of SiO₂ and six 300 nm thick second acoustic mirror material layers 13 made of W are stacked alternately on a silicon substrate 11 to form an acoustic mirror 14. Then, a 150 nm thick Au film is formed on the acoustic mirror 14 to provide a first adhesion layer 31.

As shown in FIG. 2B, a 100 nm thick buffer layer 22 made of GaN is formed on a preparation substrate 21 made of sapphire and an AlN film is epitaxially grown on the buffer layer 22 in a thickness of 500 nm to provide a piezoelectric film 23. Subsequently, a 150 nm thick Au film is deposited on the piezoelectric film 23 to form a second adhesion layer 32.

Then, as shown in FIG. 2C, a pressure of 1 to 3 MPa is applied to the substrate 11 and the preparation substrate 21 from below and above to bond the first and second adhesion layers 31 and 32. In this state, heating is carried out at 350° C. for 10 minutes to thermally bonding the first and second adhesion layers 31 and 32, thereby obtaining a bottom electrode 16.

Then, laser light is applied to the buffer layer 22 through the preparation substrate 21 by the laser lift-off method to remove the preparation substrate 21 as shown in FIG. 2D.

Then, a 300 nm thick top electrode 24 made of Mo is formed on the piezoelectric film 23 as shown in FIG. 2E.

In order to obtain an excellent resonator with less insertion loss, it is necessary to form the piezoelectric film 23 with excellent crystallinity and flatness. According to the method for manufacturing the piezoelectric resonator of the present embodiment, the piezoelectric film is epitaxially grown on the sapphire substrate and then bonded to the acoustic mirror 14. As a result, the piezoelectric film 23 is obtained with excellent quality irrespective of the degree of flatness and crystallinity of the acoustic mirror 14 and the bottom electrode 16. Thus, the piezoelectric resonator is manufactured easily with less insertion loss and excellent frequency selectivity.

In place of the epitaxially grown piezoelectric film 23, the piezoelectric film 23 may be provided by forming a highly flat metal layer made of Mo on the Si substrate by sputtering and depositing AlN on the metal layer by sputtering.

Either of the first or second adhesion layers 31 and 32 may be made of tin (Sn) such that the first and second adhesion layers 31 and 32 are bonded together by eutectic bonding between gold and tin. Likewise, the first and second adhesion layers 31 and 32 may be made of a combination of lead (Pb) and tin (Sn) such that they are bonded together by eutectic bonding.

The Si substrate 11 may be replaced with a GaAs substrate or a sapphire substrate.

### Variant of First Embodiment

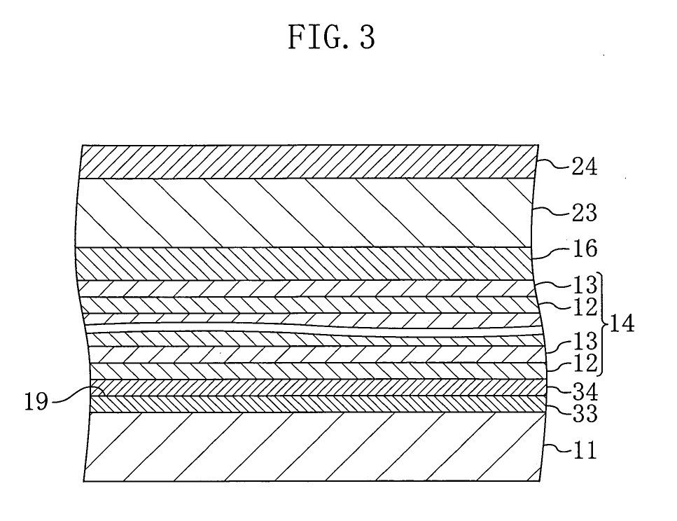

FIG. 3 shows a section of a variant of the piezoelectric resonator according to the first embodiment. In FIG. 3, the same components as those shown in FIG. 1 are indicated by the same reference numerals to omit the explanation.

As shown in FIG. 3, a third adhesion layer 33 and a fourth adhesion layer 34, both of which are made of gold, are formed on a substrate 11. On the fourth adhesion layer 34, six first acoustic mirror material layers 12 made of SiO₂ and six second acoustic mirror material layers 13 made of W are stacked alternately to form an acoustic mirror 14. A 300 nm thick bottom electrode 16 made of Mo is formed on the acoustic mirror 14. A piezoelectric film 23 made of AlN and a top electrode 24 made of Mo are formed on the bottom electrode 16.

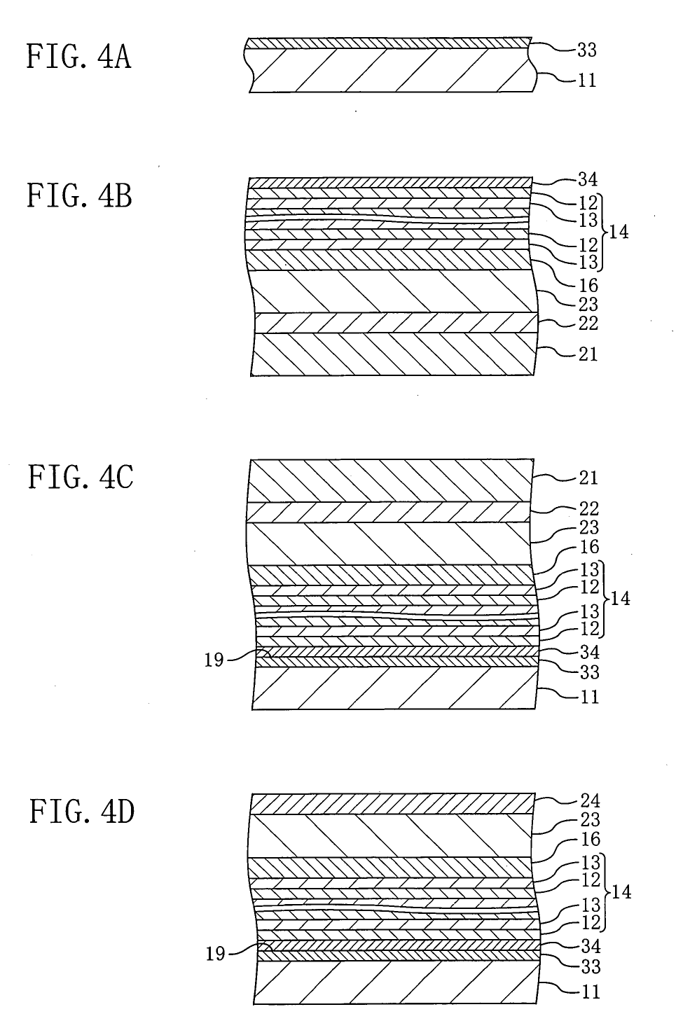

FIGS. 4A to 4D are sectional views illustrating the steps of manufacturing the variant of the piezoelectric resonator. As shown in FIG. 4A, first, a 150 nm thick Au layer is formed on the Si substrate 11 to provide a third adhesion layer 33.

Then, a buffer layer 22 made of GaN, a piezoelectric film 23 made of AlN and a bottom electrode 16 made of Mo are formed in this order on a preparation substrate 21 made of sapphire as shown in FIG. 4B. Then, six first acoustic mirror material layers 12 made of SiO₂ and six second acoustic mirror material layers made of W are stacked alternately on the top electrode 24 to form an acoustic mirror 14. Further, a 150 nm thick Au layer is formed on the acoustic mirror 14 to provide a fourth adhesion layer 34.

Then, a pressure is applied to the substrate 11 and the preparation substrate 21 from below and above to bond the third and fourth adhesion layers 33 and 34 as shown in FIG. 4C. Further, heating is carried out at 350° C. for 10 minutes to bond the third and fourth adhesion layers 33 and 34.

The preparation substrate 21 is then removed by laser lift-off and a top electrode 24 made of Mo is formed on the piezoelectric film 23 as shown in FIG. 4D.

In the variant of the piezoelectric resonator, the bottom electrode and the adhesion layers are individually provided. Therefore, the material for the bottom electrode is freely selected. The bottom electrode of the variant of the piezoelectric resonator is made of Mo having high hardness. If tungsten (W) or iridium (Ir) having excellent acoustic impedance is used as the bottom electrode, the resonator improves in selectivity (Q-value).

### SECOND EMBODIMENT

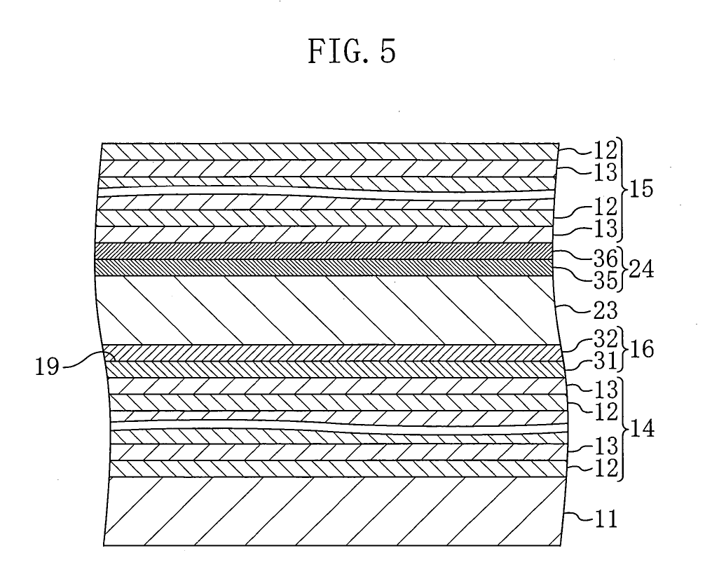

Hereinafter, an explanation of a piezoelectric resonator according to the second embodiment of the present invention will be provided with reference to the figures. FIG. 5 is a sectional view illustrating the structure of the piezoelectric resonator of the present embodiment. In FIG. 5, the same components as those shown in FIG. 1 are indicated by the same reference numerals to omit the explanation.

As shown in FIG. 5, a top acoustic mirror 15 is formed on the top electrode 24 of the piezoelectric resonator of the first embodiment. Specifically, the top electrode 24 formed on the piezoelectric film 23 includes a fifth adhesion layer 35 and a sixth adhesion layer 36, both of which are 150 nm in thickness and made of Au. The fifth and sixth adhesion layers 35 and 36 form a bonding interface 35 therebetween. The top acoustic mirror 15 on the top electrode 24 is formed by alternately stacking six first acoustic mirror material layers 12 and six second acoustic mirror material layers 13.

The piezoelectric resonator of the present embodiment additionally includes the top acoustic mirror 15 on the top electrode 24. Therefore, there is no need of keeping the piezoelectric resonator free from contact from above. Thus, the resin seal packaging of the piezoelectric resonator is allowed.

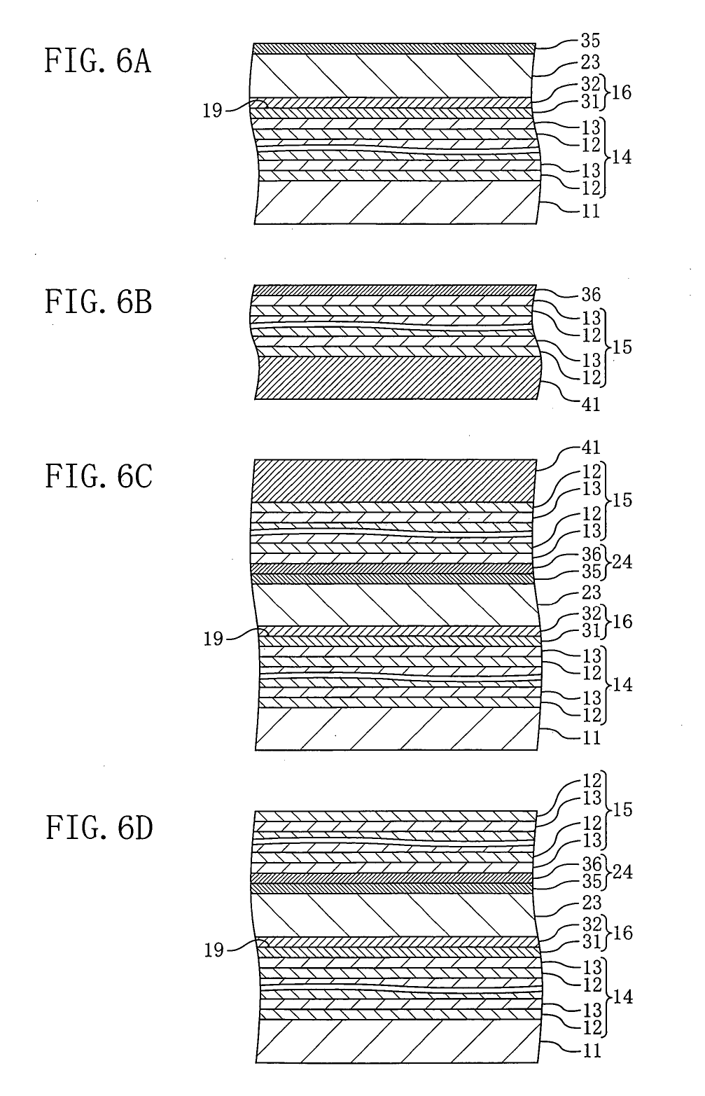

FIGS. 6A to 6D are sectional views illustrating the steps of manufacturing the piezoelectric resonator of the present embodiment. The piezoelectric resonator of the present embodiment is manufactured by the same steps as those of the first embodiment until the preparation substrate 21 is removed by laser lift-off. Therefore, an explanation of the same steps is omitted.

As shown in FIG. 6A, a 150 nm thick fifth adhesion layer 35 made of Au is formed on the piezoelectric film 23 from which the preparation substrate 21 has been removed by laser lift-off.

Then, as shown in FIG. 6B, six 300 nm thick first acoustic mirror material layers 12 made of SiO₂ and six 300 nm thick second acoustic mirror material layers made of W are stacked alternately on a Si substrate 41 to form a top acoustic mirror 15. Then, a 150 nm thick Au layer is formed on the top acoustic mirror 15 to provide a sixth adhesion layer 36.

Then, a pressure is applied to the substrates 11 and 41 from below and above to bond the fifth and sixth adhesion layers 35 and 36 as shown in FIG. 6C. In this state, heating is carried out at 350° C. for 10 minutes to bond the fifth and sixth adhesion layers 35 and 36, thereby obtaining a top electrode 24.

Subsequently, the substrate 41 is removed by polishing as shown in FIG. 6D.

In the present embodiment, the first, second, fifth and sixth adhesion layers 31, 32, 35 and 36 are made of Au such that the first and second adhesion layers 31 and 32 are thermally bonded, and so are the fifth and sixth adhesion layers 35 and 36. However, they may be bonded by eutectic bonding. In this case, if the first and second adhesion layers 31 and 32 are made of a gold-germanium alloy (Au—Ge eutectic point: about 360° C.), and if the fifth and sixth adhesion layers 35 and 36 are made of a gold-tin alloy (Au—Sn eutectic point: about 280° C.), the bonding interface between the first and second adhesion layers 32 is not affected during the bonding of the top acoustic mirror 15 because the Au—Sn eutectic point is lower than the Au—Ge eutectic point.

Alternatively, the top acoustic mirror 15 may be formed by alternately depositing the first acoustic mirror material layers 12 made of SiO₂ and the second acoustic mirror material layers 13 made of W directly on the top electrode made of Mo which has been formed in the same manner as the first embodiment.

In the present embodiment, the top acoustic mirror is formed on the piezoelectric resonator of the first embodiment. Alternatively, the top acoustic mirror may be formed on the variant of the piezoelectric resonator of the first embodiment.

### THIRD EMBODIMENT

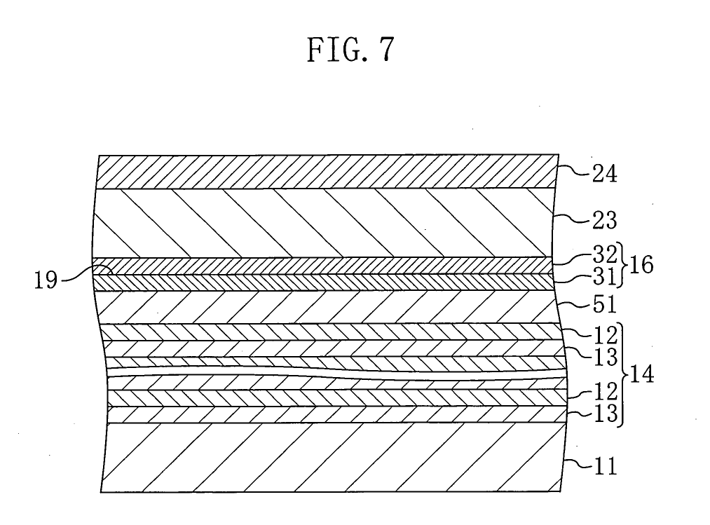

Hereinafter, an explanation of a piezoelectric resonator according to the third embodiment of the present invention will be provided with reference to the figures. FIG. 7 shows a section of the piezoelectric resonator of the present embodiment. In FIG. 7, the same components as those shown in FIG. 1 are indicated by the same reference numerals to omit the explanation.

As shown in FIG. 7, the piezoelectric resonator of the present embodiment includes a 50 nm thick barrier metal layer 51 made of nickel (Ni) between the acoustic mirror 14 and the bottom electrode 16.

When metal is brought into contact with another metal, interdiffusion occurs between these metals. The probability of the occurrence of the interdiffusion varies greatly depending on the kind of metals contacting each other, temperatures, and so on. For example, it has been known that Ti and Au cause significant interdiffusion (see “Journal of Material Science”, 1993, Vol. 28, pp. 5088-5091, for example). When a stack of Ti and Au is heated at 250° C., the interface between Ti and Au becomes unclear and irregularities are observed on the surface. The interdiffusion changes the composition of Ti and Au, as well as the structure thereof such as thickness.

In light of the above, if the bottom electrode 16 is made of Au and the first acoustic mirror material layer 12 serving as the uppermost layer of the acoustic mirror 14 is made of Ti, interdiffusion occurs between the bottom electrode 16 and the first acoustic mirror material layer 12, thereby changing the composition and thickness of the bottom electrode 16 and the first acoustic mirror material layer 12. As a result, the resonance frequency of the piezoelectric resonator varies, thereby greatly deteriorating the frequency characteristic of the piezoelectric resonator.

In the present embodiment, the barrier metal layer 51 made of Ni is provided between the uppermost first acoustic mirror material layer 12 made of Ti formed at the uppermost of the acoustic mirror 14 and the bottom electrode 16. The degree of interdiffusion between Au and Ni or Ti and Ni is very small as compared with the interdiffusion between Au and Ti. Therefore, the composition and thickness of the bottom electrode 16 and the first acoustic mirror material layer 12 are hardly changed, thereby preventing the deterioration in frequency characteristic of the piezoelectric resonator.

Material and thickness of the barrier metal layer 51 according to the present embodiment need to be changed depending on the materials of the bottom electrode 16 and the first acoustic mirror material layer 12. When the bottom electrode 16 and the first acoustic mirror material layer 12 are made of Au and Ti, respectively, the barrier metal layer 51 may be made of platinum (Pt).

In the present embodiment, the uppermost layer of the acoustic mirror 14 is the first acoustic mirror material layer 12. Even when the second acoustic mirror material layer 13 is the uppermost layer of the acoustic mirror 14, the interdiffusion between the bottom electrode 16 and the second acoustic mirror material layer 13 is prevented in the same manner as described above.

### Variant of Third Embodiment

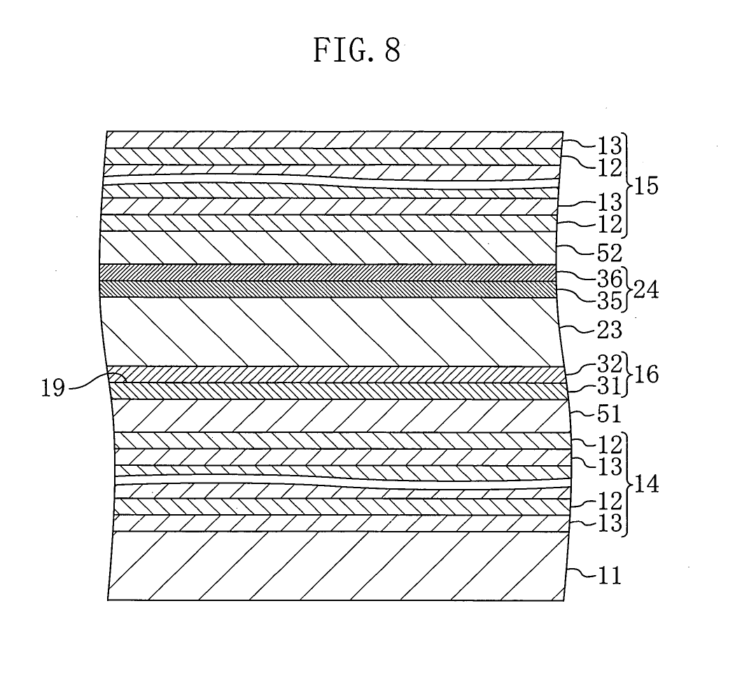

FIG. 8 illustrates a section of a variant of the piezoelectric resonator according to the third embodiment. In FIG. 8, the same components as those shown in FIG. 7 are indicated by the same reference numerals to omit the explanation.

As shown in FIG. 8, in the variant of the third embodiment, a barrier metal layer 52 is formed on the top electrode 24 and a top acoustic mirror 15 is formed on the barrier metal layer 52.

Therefore, interdiffusion is prevented from occurring between the top electrode 24 and the first acoustic mirror material layer of the top acoustic mirror 15.

As described above, the piezoelectric resonator and the method for manufacturing the same according to the present invention make it possible to use a piezoelectric film with high crystallinity and excellent flatness in a piezoelectric resonator including an acoustic mirror. As the present invention achieves a piezoelectric resonator with less insertion loss and excellent frequency selectivity and a method for manufacturing the same, the present invention is useful for a resonator applicable to a high frequency filter in an electronic circuit and a method for manufacturing the same.

What is claimed is:

1. A piezoelectric resonator comprising:
a substrate;
an acoustic mirror formed on the substrate and includes alternately stacked first acoustic mirror material layers and second acoustic mirror material layers having higher acoustic impedance than that of the first acoustic mirror material layers;
a piezoelectric film formed on the acoustic mirror;
a top electrode formed on the piezoelectric film; and
a bottom electrode formed below the piezoelectric film, wherein
a bonding interface is provided between metal films bonded to each other between the substrate and the piezoelectric film.

2. The piezoelectric resonator according to claim 1, wherein
the first acoustic mirror material layers are made of any one of silicon oxide, aluminum, titanium and gallium nitride.

3. The piezoelectric resonator according to claim 1, wherein
the second acoustic mirror material layers are made of any one of tungsten, iridium, aluminum nitride and molybdenum.

4. The piezoelectric resonator according to claim 1 further comprising
adhesion layers which are formed between the substrate and the acoustic mirror and made of metal, wherein
the bonding interface is provided between the adhesion layers.

5. The piezoelectric resonator according to claim 1, wherein
the bonding interface is provided in the bottom electrode.

6. The piezoelectric resonator according to claim 1, wherein
the metal films for providing the bonding interface are made of gold, a gold-tin alloy, a gold-germanium alloy or a lead-tin alloy.

7. The piezoelectric resonator according to claim 1 further comprising
a first barrier metal layer which is formed between the bottom electrode and the acoustic mirror to prevent interdiffusion between the bottom electrode and the acoustic mirror.

8. The piezoelectric resonator according to claim 7, wherein
the first barrier metal layer is made of nickel or platinum.

9. The piezoelectric resonator according to claim 1 further comprising
a top acoustic mirror formed on the top electrode and includes the first acoustic mirror material layers and the second acoustic mirror material layers which are alternately stacked.

10. The piezoelectric resonator according to claim 9, wherein
the top electrode is made of metal films bonded to each other.

11. The piezoelectric resonator according to claim 9 further comprising
a second barrier metal layer which is formed between the top electrode and the top acoustic mirror to prevent interdiffusion between the top electrode and the top acoustic mirror.

12. The piezoelectric resonator according to claim 11, wherein
the second barrier metal layer is made of nickel or platinum.

13. A method for manufacturing a piezoelectric resonator comprising the steps of:
(a) alternately stacking first acoustic mirror material layers and second acoustic mirror material layers having higher impedance than that of the first acoustic mirror material layers on a first substrate to form an acoustic mirror and forming a first bottom electrode layer on the acoustic mirror;
(b) forming a piezoelectric film on a second substrate and forming a second bottom electrode layer on the piezoelectric film;
(c) bonding the first bottom electrode layer formed above the first substrate and the second bottom electrode layer formed above the second substrate to form a bottom electrode; and
(d) removing the second substrate from the piezoelectric film.

14. The method for manufacturing a piezoelectric resonator according to claim 13, wherein
the first bottom electrode layer and the second bottom electrode layer are both made of gold and
the step (c) is the step of bonding the first bottom electrode layer and the second bottom electrode layer by thermocompression bonding.

15. The method for manufacturing a piezoelectric resonator according to claim 13, wherein
the first bottom electrode layer and the second bottom electrode layer are made of a gold-tin alloy, a gold-germanium alloy or a lead-tin alloy and
the step (c) is the step of bonding the first bottom electrode layer and the second bottom electrode layer by eutectic bonding.

16. The method for manufacturing a piezoelectric resonator according to claim 13, wherein
the step (a) includes the step of forming a first barrier metal layer between the acoustic mirror and the first bottom electrode layer to prevent interdiffusion between the acoustic mirror and the bottom electrode.

17. The method for manufacturing a piezoelectric resonator according to claim 16, wherein
the first barrier metal layer is made of nickel or platinum.

18. The method for manufacturing a piezoelectric resonator according to claim 13 further comprising, after the step (d), the steps of:
(e) forming a top electrode on the piezoelectric film from which the second substrate has been removed; and
(f) alternately stacking the first acoustic mirror material layers and the second acoustic mirror materials on the top electrode to form a top acoustic mirror.

19. The method for manufacturing a piezoelectric resonator according to claim 13 further comprising, after the step (d), the steps of:
(g) forming a first top electrode layer on the piezoelectric film from which the second substrate has been removed;
(h) alternately stacking the first acoustic mirror material layers and the second acoustic mirror material layers on a third substrate to form a top acoustic mirror and forming a second top electrode layer on the top acoustic mirror;
(i) bonding the first top electrode layer and the second top electrode layer to form a top electrode; and
(j) removing the third substrate from the top acoustic mirror.

20. The method for manufacturing a piezoelectric resonator according to claim 19, wherein
the first top electrode layer and the second top electrode layer are both made of gold and
the step (i) is the step of bonding the first top electrode layer and the second top electrode layer by thermocompression bonding.

21. The method for manufacturing a piezoelectric resonator according to claim 19, wherein
the first top electrode layer and the second top electrode layer are made of a combination of gold and tin, gold and germanium or lead and tin and
the step (i) is the step of bonding the first top electrode layer and the second top electrode layer by eutectic bonding.

22. The method for manufacturing a piezoelectric resonator according to claim 19, wherein
the step (h) includes the step of forming a second barrier metal layer between the top acoustic mirror and the second top electrode layer to prevent interdiffusion between the top acoustic mirror and the top electrode.

23. The method for manufacturing a piezoelectric resonator according to claim 22, wherein
the second barrier metal layer is made of nickel or platinum.

24. A method for manufacturing a piezoelectric resonator comprising the steps of:
(a) forming a first adhesion layer on a first substrate;
(b) forming a piezoelectric film, a bottom electrode, an acoustic mirror including alternately stacked first acoustic mirror material layers and second acoustic mirror material layers having higher impedance than that of the first acoustic mirror material layers and a second adhesion layer in this order on a second substrate;
(c) bonding the first adhesion layer formed on the first substrate and the second adhesion layer formed above the second substrate; and
(d) removing the second substrate from the piezoelectric film.

25. The method for manufacturing a piezoelectric resonator according to claim 24, wherein
the first adhesion layer and the second adhesion layer are both made of gold and
the step (c) is the step of boding the first adhesion layer and the second adhesion layer by thermocompression bonding.

26. The method for manufacturing a piezoelectric resonator according to claim 24, wherein
the first adhesion layer and the second adhesion layer are made of a combination of gold and tin, gold and germanium or lead and tin and
the step (c) is the step of boding the first adhesion layer and the second adhesion layer by eutectic bonding.

27. The method for manufacturing a piezoelectric resonator according to claim 24 further comprising, after the step (d), the steps of:
(i) forming a top electrode on the piezoelectric film; and
(j) alternately stacking the first acoustic mirror material layers and the second acoustic mirror material layers on the top electrode to form a top acoustic mirror.
